(19) United States
(12) Patent Application Publication
(10) Pub. No.: US 2026/0363123 A1
(43) Pub. Date: Nov. 12, 2026

(54) SEMICONDUCTOR DEVICE, METHOD OF MANUFACTURING THE SAME, AND MODULE

(71) Applicant: SUMITOMO ELECTRIC INDUSTRIES, LTD., Osaka (JP)

(72) Inventor: Yutaka MORIYAMA, Osaka (JP)

(21) Appl. No.: 19/639,478

(22) Filed: Apr. 6, 2026

(30) Foreign Application Priority Data
May 7, 2025 (JP) 2025-077564

(51) Int. Cl. H10W 70/695; H10W 40/20; H10W 44/20; H10W 70/09; H10W 70/60; H10W 74/47; H10W 90/10; H10W 70/20

(52) U.S. Cl. CPC H10W 70/695; H10W 40/235; H10W 44/226; H10W 70/09; H10W 70/614; H10W 74/473; H10W 90/10; H10W 70/20

(57) ABSTRACT

A semiconductor device includes a base, a semiconductor chip, a first resin layer, an interconnect, an electronic component, a second resin layer, a through electrode, and an external terminal. The through electrode includes a layer whose main component is a same element as a main component of the interconnect, the layer of the through electrode and the interconnect being directly connected to each other. The through electrode includes a first region in contact with the interconnect and a second region in contact with the external terminal, and a width of the first region is equal to or greater than 0.7 times a width of the second region.

### CROSS REFERENCE TO RELATED APPLICATIONS

This application claims priority to Japanese Patent Application No. 2025-077564 filed on May 7, 2025, and the entire contents of the Japanese patent application are incorporated herein by reference.

### TECHNICAL FIELD

The present disclosure relates to a semiconductor device, a method of manufacturing the same, and a module.

### BACKGROUND

A semiconductor device is known in which a semiconductor chip is mounted on a base, an electronic component is mounted on wiring provided on a resin layer covering the semiconductor chip, and an external terminal electrically connected to the wiring is provided on the resin layer that covers the electronic component (see, for example, Patent Literature 1: Japanese Unexamined Patent Application Publication No. 2023-133675 and Patent Literature 2: Japanese Unexamined Patent Application Publication No. 2023-133676). As a method of forming a through electrode in a resin layer, a method of radiating a laser beam is known (see, for example, Patent Literature 3: Japanese Unexamined Patent Application Publication No. 2014-82353 and Patent Literature 4: Japanese Unexamined Patent Application Publication No. 2021-141226). A method of forming a resin layer after bonding a protruding terminal to wiring is known (see, for example, Patent Literature 5: Japanese Unexamined Patent Application Publication No. 2015-230990).

### SUMMARY

A semiconductor device according to an embodiment of the present disclosure includes a base, a semiconductor chip mounted on the base, a first resin layer covering the semiconductor chip and provided on the base, an interconnect provided on the first resin layer and electrically connected to the semiconductor chip, an electronic component mounted on the interconnect and electrically connected to the interconnect, a second resin layer covering the electronic component and provided on the first resin layer, a through electrode penetrating the second resin layer and electrically connected to the interconnect, and an external terminal provided on the second resin layer and electrically connected to the through electrode. The through electrode includes a layer whose main component is a same element as a main component of the interconnect, the layer of the through electrode and the interconnect being directly connected to each other, and the through electrode includes a first region in contact with the interconnect and a second region in contact with the external terminal, and a width of the first region is equal to or greater than 0.7 times a width of the second region.

A method of manufacturing a semiconductor device according to an embodiment of the present disclosure includes: preparing a member including a base, a semiconductor chip mounted on the base, a first resin layer covering the semiconductor chip and provided on the base, and an interconnect provided on the first resin layer and electrically connected to the semiconductor chip; mounting an electronic component on the interconnect of the member; mounting a resin member on the interconnect; forming a second resin layer on the first resin layer so as to cover the electronic component and the resin member and expose an upper surface of the resin member from the second resin layer; forming a through hole connected to the interconnect by removing the resin member; and forming a through electrode electrically connected to the interconnect in the through hole and an external terminal electrically connected to the through electrode on the second resin layer.

### BRIEF DESCRIPTION OF THE DRAWINGS

FIG. 1 is a cross-sectional view of a semiconductor device according to a first embodiment.

FIG. 2A is a cross-sectional view showing a method of manufacturing the semiconductor device according to the first embodiment.

FIG. 2B is a cross-sectional view showing the method of manufacturing the semiconductor device according to the first embodiment.

FIG. 2C is a cross-sectional view showing the method of manufacturing the semiconductor device according to the first embodiment.

FIG. 3A is a cross-sectional view showing the method of manufacturing the semiconductor device according to the first embodiment.

FIG. 3B is a cross-sectional view showing the method of manufacturing the semiconductor device according to the first embodiment.

FIG. 4A is a cross-sectional view showing the method of manufacturing the semiconductor device according to the first embodiment.

FIG. 4B is a cross-sectional view showing the method of manufacturing the semiconductor device according to the first embodiment.

FIG. 5A is a cross-sectional view showing the method of manufacturing the semiconductor device according to the first embodiment.

FIG. 5B is a cross-sectional view showing the method of manufacturing the semiconductor device according to the first embodiment.

FIG. 6A is a cross-sectional view showing the method of manufacturing the semiconductor device according to the first embodiment.

FIG. 6B is a cross-sectional view showing the method of manufacturing the semiconductor device according to the first embodiment.

FIG. 7A is a cross-sectional view showing the method of manufacturing the semiconductor device according to the first embodiment.

FIG. 7B is a cross-sectional view showing the method of manufacturing the semiconductor device according to the first embodiment.

FIG. 8 is a cross-sectional view showing the method of manufacturing the semiconductor device according to the first embodiment.

FIG. 9A is a cross-sectional view showing a method of manufacturing a semiconductor device according to a first comparative embodiment.

FIG. 9B is a cross-sectional view showing the method of manufacturing the semiconductor device according to the first comparative embodiment.

FIG. 10 is a cross-sectional view showing the method of manufacturing the semiconductor device according to the first comparative embodiment.

FIG. 11 is an enlarged cross-sectional view of a through electrode of the semiconductor device according to the first comparative embodiment.

FIG. 12A is a cross-sectional view showing a method of manufacturing a semiconductor device according to a second comparative embodiment.

FIG. 12B is a cross-sectional view showing the method of manufacturing the semiconductor device according to the second comparative embodiment.

FIG. 13 is an enlarged cross-sectional view of a through electrode of the semiconductor device according to the second comparative embodiment.

FIG. 14 is an enlarged cross-sectional view of a through electrode of the semiconductor device according to the first embodiment.

FIG. 15 is a cross-sectional view showing a module according to the second embodiment.

FIG. 16 is a block diagram of an amplification circuit according to a third embodiment.

### DETAILED DESCRIPTION

In the semiconductor devices as disclosed in Patent Literature 1 and 2, the resin layer covering the electronic component may be thick. Thus, when the laser beam is used as a method of forming the through electrode penetrating the resin layer, as in Patent Literature 3 and 4, the through electrode is thin and resistance of the through electrode is high. When a pillar such as the protruding terminal is bonded to the wiring as in Patent Literature 5, contact resistance between the pillar and the wiring increases. Also, the pillar is easily peeled off from the wiring.

An object of the present disclosure is to provide a semiconductor device, a method of manufacturing the same, and a module that can appropriately connect an external terminal and an interconnect to each other.

According to the present disclosure, it is possible to provide a semiconductor device, a method of manufacturing the same, and a module that can appropriately connect an external terminal and an interconnect to each other.

### Description of Embodiments of Present Disclosure

First, embodiments of the present disclosure will be listed and described.
(1) A semiconductor device according to an embodiment of the present disclosure includes a base, a semiconductor chip mounted on the base, a first resin layer covering the semiconductor chip and provided on the base, an interconnect provided on the first resin layer and electrically connected to the semiconductor chip, an electronic component mounted on the interconnect and electrically connected to the interconnect, a second resin layer covering the electronic component and provided on the first resin layer, a through electrode penetrating the second resin layer and electrically connected to the interconnect, and an external terminal provided on the second resin layer and electrically connected to the through electrode. The through electrode and the interconnect are directly connected to a layer whose main component is the same element as an element that is a main component of the interconnect. The through electrode has a first region in contact with the interconnect and a second region in contact with the external terminal, the first region having a width that is 0.7 or more times a width of the second region. This can reduce contact resistance between the through electrode and the interconnect and increase bonding strength between the through electrode and the interconnect. Thus, the external terminal and the interconnect can be appropriately connected. (
2) In the above (1), the second resin layer may include fillers. Thus, even when the second resin layer includes the fillers, the external terminal and the interconnect can be appropriately connected.
(3) In the above (1) or (2), the second resin layer may have a thickness larger than the width of the second region. Thus, even when the thickness of the second resin layer is larger than the width of the second region, the external terminal and the interconnect can be appropriately connected.
(4) In any one of the above (1) to (3), the base may have a surface to which a heat dissipation member is connectable, the surface being opposite to a surface on which the semiconductor chip is mounted. The external terminal may be electrically connectable to a mounting substrate. Thus, even when heat is dissipated from the base, and an electrical connection between the external terminal and a mounting substrate is performed, the external terminal and the interconnect can be appropriately connected.
(5) In any one of the above (1) to (4), the interconnect may include a first interconnect through which a high frequency signal input to the semiconductor chip is configured to be transmitted and a second interconnect through which the high frequency signal output from the semiconductor chip is configured to be transmitted. The through electrode may include a first through electrode electrically connected to the first interconnect and a second through electrode electrically connected to the second interconnect. The external terminal may include a first external terminal electrically connected to the first through electrode and a second external terminal electrically connected to the second through electrode. This can improve high-frequency characteristics.
(6) In the above (5), the semiconductor chip may include an amplifier that amplifies the high frequency signal. This makes it possible to appropriately connect the external terminal and the interconnect in the amplification circuit.
(7) A module according to an embodiment of the present disclosure includes the semiconductor device according to any one of the above (1) to (6), a heat dissipation member bonded to a surface of the base opposite to a surface on which the semiconductor chip is mounted, and a mounting substrate electrically connected to the external terminal. Thus, even when heat is dissipated from the base, and an electrical connection between the external terminal and a mounting substrate is performed, the external terminal and the interconnect can be appropriately connected.
(8) A method of manufacturing a semiconductor device according to an embodiment of the present disclosure includes: preparing a member including a base, a semiconductor chip mounted on the base, a first resin layer covering the semiconductor chip and provided on the base, and an interconnect provided on the first resin layer and electrically connected to the semiconductor chip; mounting an electronic component on the interconnect of the member; mounting a resin member on the interconnect; forming a second resin layer on the first resin layer so as to cover the electronic component and the resin member and expose an upper surface of the resin member from the second resin layer; forming a through hole connected to the interconnect by removing the resin member; and forming a through electrode electrically connected to the interconnect in the through hole and an external terminal electrically connected to the through electrode on the second resin layer. This can reduce the contact resistance between the through electrode and the interconnect and increase the bonding strength between the through electrode and the interconnect. Thus, the external terminal and the interconnect can be appropriately connected.
(9) In the above (8), the second resin layer may include first fillers. The resin member may include second fillers having an average particle diameter smaller than an average particle diameter of the first fillers, or may include no filler. The forming the through hole may include forming the through hole by irradiating the resin member with a laser beam. Thus, even when the second resin layer includes the fillers, the external terminal and the interconnect can be appropriately connected.
(10) In the above (8) or (9), the forming the through electrode may include forming the through electrode using plating. This allows the through electrode and the interconnect to be directly connected to each other.

### Details of Embodiments of Present Disclosure

Specific examples of a semiconductor device, a method of manufacturing the same, and a module according to embodiments of the present disclosure will be described below with reference to the drawings. The present disclosure is not limited to these examples, but is defined by the scope of the claims, and is intended to include all modifications within the meaning and scope equivalent to the scope of the claims.

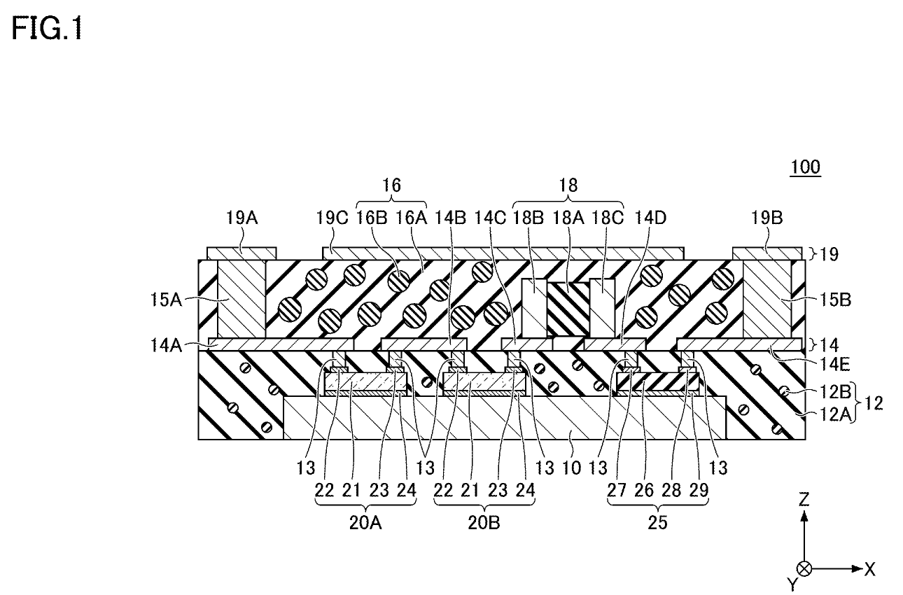

FIG. 1 is a cross-sectional view of a semiconductor device according to a first embodiment. A thickness direction of a base 10, that is, a stacking direction of the base 10 and resin layers 12 and 16 is defined as a Z direction, and directions orthogonal to the Z direction and to each other are defined as an X direction and a Y direction. As shown in FIG. 1, a semiconductor device 100 includes the base 10, semiconductor chips 20A and 20B, the resin layers 12 and 16, via interconnects 13, an interconnect 14, through electrodes 15A and 15B, an electronic component 18, and external terminals 19A, 19B, and 19C, and a passive chip 25.

The semiconductor chips 20A and 20B and the passive chip 25 are mounted on the base 10. The semiconductor chips 20A and 20B each include a substrate 21 and electrodes 22, 23, and 24. The electrodes 22 and 23 are provided on an upper surface of the substrate 21. The electrode 24 is provided on a lower surface of the substrate 21. The passive chip 25 includes a substrate 26 and electrodes 27, 28, and 29. The electrodes 27 and 28 are provided on an upper surface of the substrate 26. The electrode 29 is provided on a lower surface of the substrate 26. The electrodes 24 and 29 are bonded onto the base 10 using a conductive bonding material. When a reference potential such as a ground potential is supplied to the base 10, the reference potential is supplied to the electrodes 24 and 29.

The resin layer 12 is provided on the base 10 so as to cover the semiconductor chips 20A and 20B and the passive chip 25. The resin layer 12 includes a resin 12A and fillers 12B. Each via interconnect 13 penetrates the resin layer 12. The interconnect 14 is provided on the resin layer 12. The interconnect 14 includes interconnects 14A to 14E. The interconnect 14 is electrically connected to the electrodes 22, 23, 27, and 28 via the via interconnects 13. The electronic component 18 is mounted on the interconnect 14. The electronic component 18 includes a body 18A, and electrodes 18B and 18C. The electrodes 18B and 18C are provided on a surface of the body 18A. The electrodes 18B and 18C are bonded onto the interconnect 14 using, for example, a conductive bonding material.

The resin layer 16 is provided on the resin layer 12 so as to cover the interconnect 14 and the electronic component 18. The resin layer 16 includes a resin 16A and fillers 16B. The through electrodes 15A and 15B penetrate the resin layer 16. An external terminal 19 is provided on the resin layer 16. The external terminal 19 includes external terminals 19A, 19B, and 19C. The external terminals 19A and 19B are electrically connected to the interconnect 14 via the through electrodes 15A and 15B, respectively.

The external terminal 19A is electrically connected to the interconnect 14A via the through electrode 15A. The external terminal 19B is electrically connected to the interconnect 14E via the through electrode 15B. The interconnect 14A electrically connects the through electrode 15A and the electrode 22 of the semiconductor chip 20A to each other. The interconnect 14B electrically connects the electrode 23 of the semiconductor chip 20A and the electrode 22 of the semiconductor chip 20B to each other. The interconnect 14C electrically connects the electrode 23 of the semiconductor chip 20B and the electrode 18B of the electronic component 18 to each other. The interconnect 14D electrically connects the electrode 18C of the electronic component 18 and the electrode 27 of the passive chip 25 to each other. The interconnect 14E electrically connects the through electrode 15B and the electrode 28 of the passive chip 25 to each other.

When the semiconductor device 100 processes a high frequency signal, the high frequency signal is input to the external terminal 19A from an external device or an external circuit, for example. The semiconductor chips 20A and 20B process the high frequency signal. For example, the semiconductor chips 20A and 20B amplify the high frequency signal. The external terminal 19B outputs the high frequency signal processed by the semiconductor chips 20A and 20B to an external device or an external circuit.

At least an upper surface of the base 10 is a conductor, and is a metal plate such as a copper plate, a laminated plate of copper, molybdenum, and copper, or the like. The base 10 may be an insulating layer. The resins 12A and 16A are formed of, for example, epoxy resin or polyimide resin. The fillers 12B and 16B are, for example, inorganic insulators such as silicon oxide. A particle diameter of the fillers 16B is larger than a particle diameter of the fillers 12B, for example. The via interconnects 13, the interconnect 14, the through electrodes 15A and 15B, and the external terminal 19 are metal layers such as copper layers.

The semiconductor chips 20A and 20B have transistors such as field effect transistors (FETs). The substrate 21 is, for example, a semiconductor substrate. The electrodes 22, 23, and 24 are metal layers of gold, copper, aluminum, or the like, for example. The transistor is, for example, a gallium nitride high electron mobility transistor (GaN HEMT). The transistor may be a laterally diffused metal oxide semiconductor (LDMOS). When the transistor is a GaN HEMT, the substrate 21 is, for example, a silicon carbide substrate. When the transistor is an LDMOS, the substrate 21 is a silicon substrate. The electrodes 22, 23, and 24 are metal layers such as gold layers, copper layers, or aluminum layers. The semiconductor chips 20A and 20B may be integrated circuits such as monolithic microwave integrated circuits (MMICs).

The passive chip 25 has, for example, a capacitor or an inductor. The substrate 26 is a dielectric substrate, and is, for example, an alumina substrate or a barium titanate substrate. The electrodes 27, 28, and 29 are metal layers of, for example, gold, copper, aluminum, or nickel. The electronic component 18 is, for example, a surface mount technology (SMT) component, and is a chip capacitor, a chip inductor, or a chip resistor, which is a discrete component.

FIG. 1 shows an example in which one semiconductor chip 20A, one semiconductor chip 20B, one passive chip 25, and one electronic component 18 are provided. One or three or more semiconductor chips 20A and 20B in total may be provided. The passive chip 25 may not be provided, or two or more passive chips 25 may be provided. Two or more electronic components 18 may be provided.

### Method of Manufacturing in First Embodiment

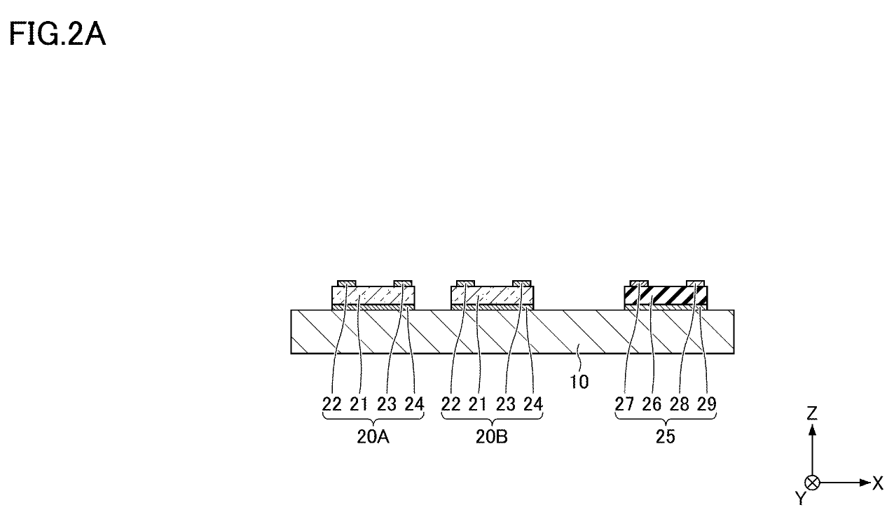

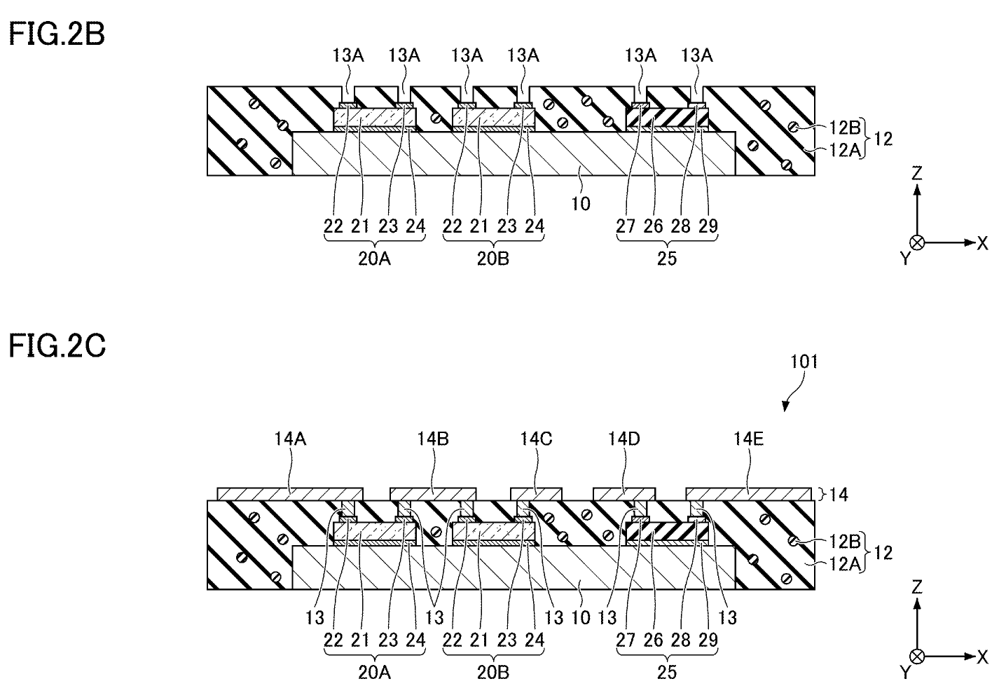

FIGS. 2A-8 are cross-sectional views each showing a method of manufacturing the semiconductor device according to the first embodiment. As shown in FIG. 2A, the semiconductor chips 20A and 20B and the passive chip 25 are mounted on the base 10. For example, a conductive bonding material, which is a metal paste such as a nano silver paste, is partially applied on the base 10. Then, the semiconductor chips 20A and 20B and the passive chip 25 are mounted on the conductive bonding material and are subjected to heat treatment. The heat treatment sinters the conductive bonding material. As a result, the semiconductor chips 20A and 20B and the passive chip 25 are mounted on the base 10.

Next, as shown in FIG. 2B, the resin layer 12 is formed so as to cover the semiconductor chips 20A and 20B and the passive chip 25. For example, a resin film is attached to the base 10 using a vacuum laminator, and the resin layer 12 is cured by heat treatment. Thus, the resin layer 12 is formed. The resin layer 12 may be formed by applying a softened resin onto the base 10 and curing the resin by heat treatment as in a molding process. A via hole 13A penetrating the resin layer 12 is formed. The via hole 13A is formed by irradiating the resin layer 12 with a laser beam, for example.

Next, as shown in FIG. 2C, a metal layer is formed on the resin layer 12 and in the via hole 13A. The metal layer is formed using, for example, plating. The metal layer in the via hole 13A is a via interconnect 13. The interconnect 14 is formed by removing a desired region of the metal layer by using, for example, etching. As a result, a member 101 including the base 10, the semiconductor chips 20A and 20B, the resin layer 12, and the interconnects 14A to 14E is prepared. The via interconnect 13 may be formed using a metal pillar.

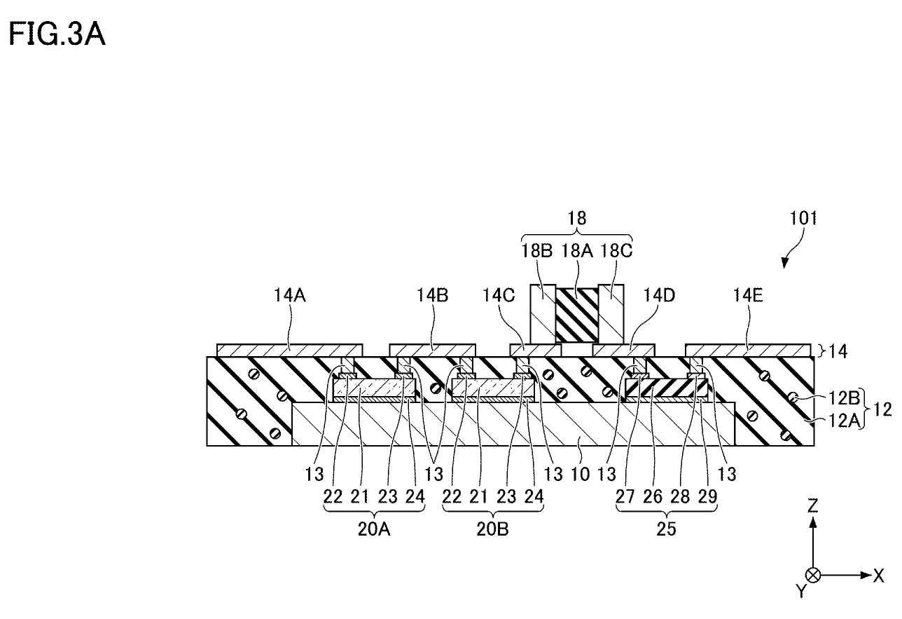

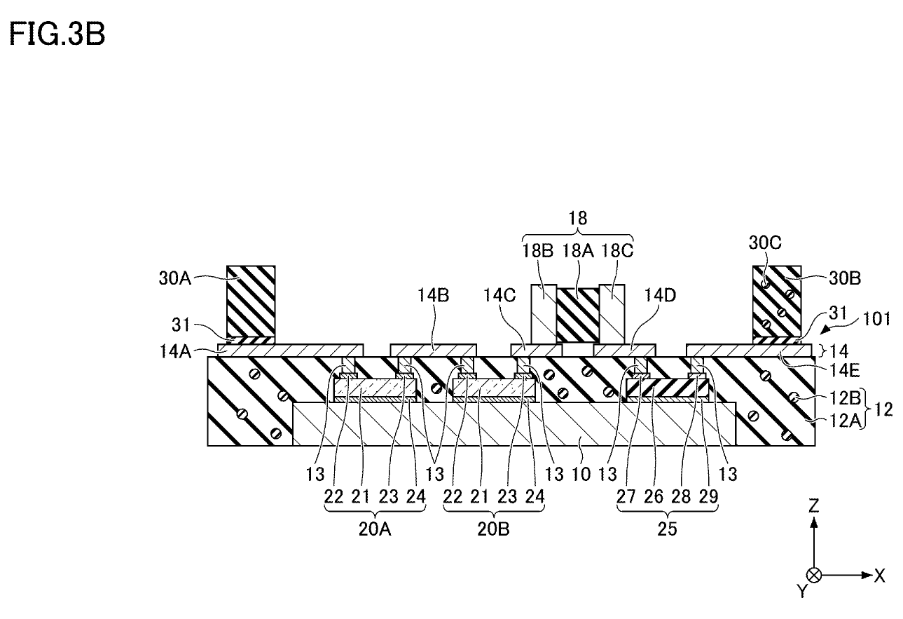

Next, as shown in FIG. 3A, the electronic component 18 is mounted on the interconnect 14. The electrodes 18B and 18C are bonded on the interconnects 14C and 14D, respectively, using a conductive bonding material such as solder.

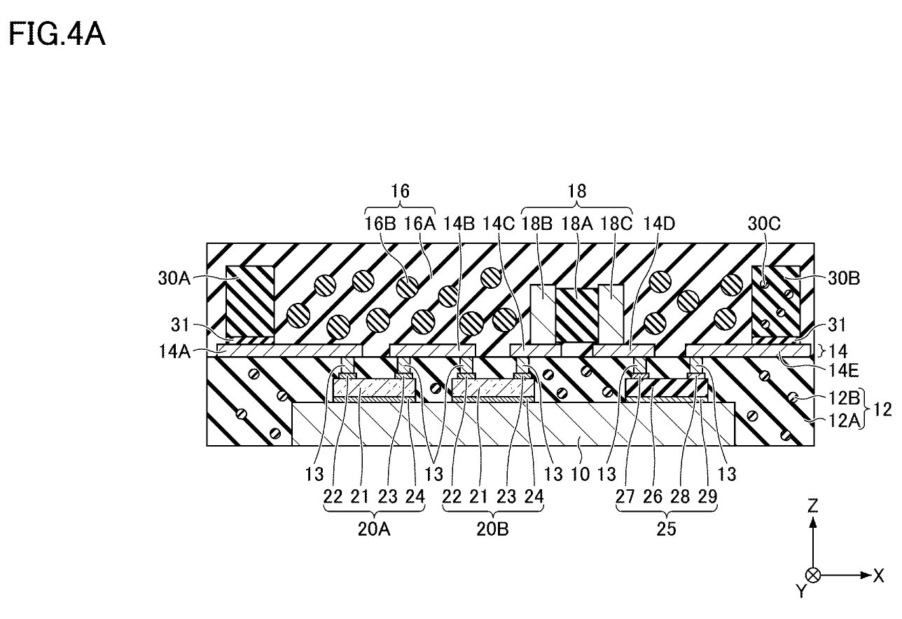

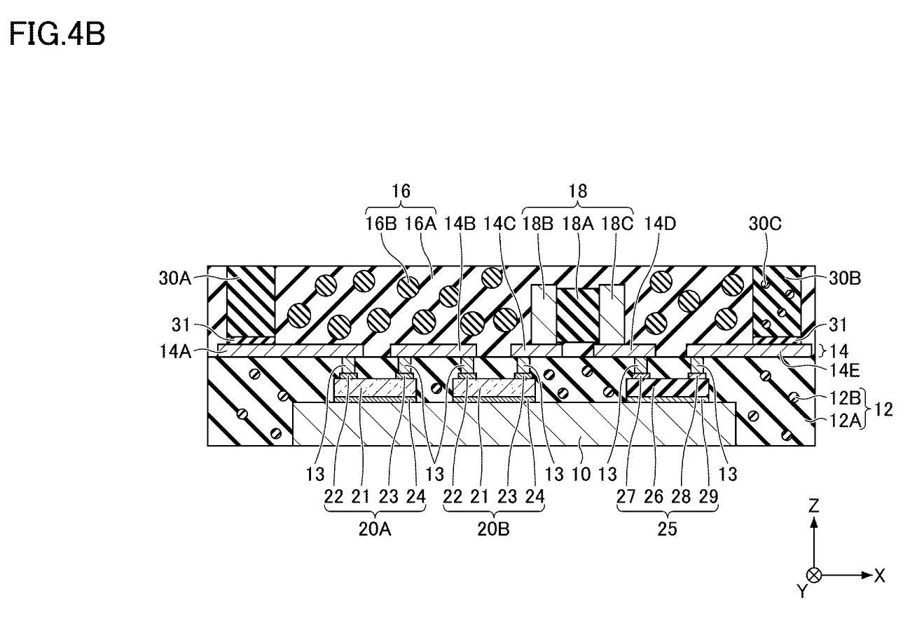

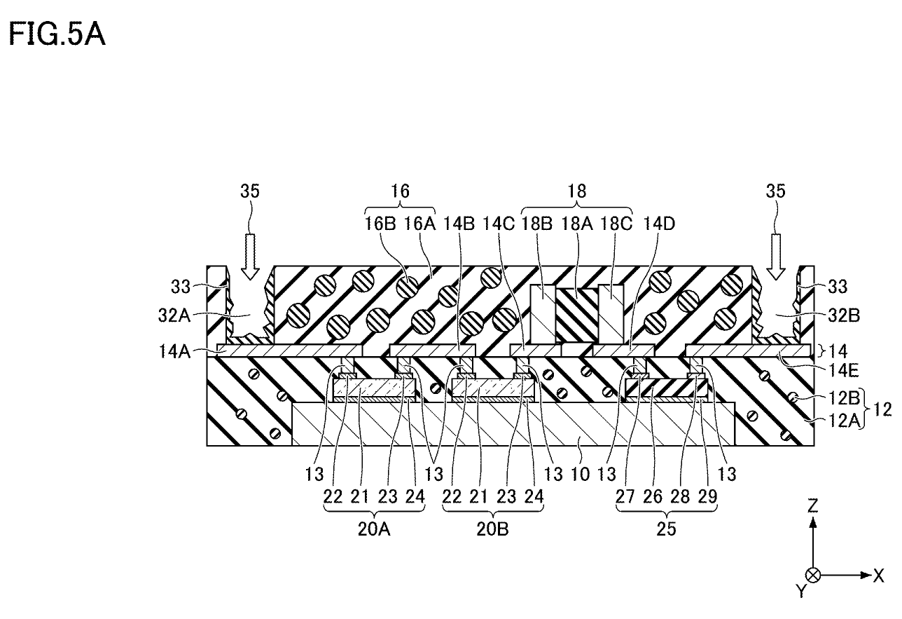

Next, as shown in FIG. 3B, resin members 30A and 30B are mounted on the interconnect 14. In FIGS. 3B-4B, for convenience, the resin member 30A is shown as a resin member having no filler, and the resin member 30B is shown as a resin member having fillers 30C. In practice, it is common that neither of the resin members 30A and 30B has fillers, or both of the resin members 30A and 30B have the fillers 30C.

The resin members 30A and 30B are bonded on the interconnects 14A and 14B, respectively, using an adhesive 31. The resin members 30A and 30B include no filler, like the resin member 30A. The resin members 30A and 30B may have the fillers 30C having an average particle diameter smaller than an average particle diameter of the fillers 16B like the resin member 30B. The resin members 30A and 30B are, for example, epoxy resin or polyimide resin. The fillers 30C are an inorganic insulator such as silicon oxide.

Next, as shown in FIG. 4A, the resin layer 16 is formed on the resin layer 12 so as to cover the electronic component 18 and the resin members 30A and 30B. The resin layer 16 is formed using, for example, the same laminating method or molding as that used for forming the resin layer 12.

Next, as shown in FIG. 4B, an upper surface of the resin layer 16 is ground or polished. As a result, the resin members 30A and 30B are exposed from the resin layer 16.

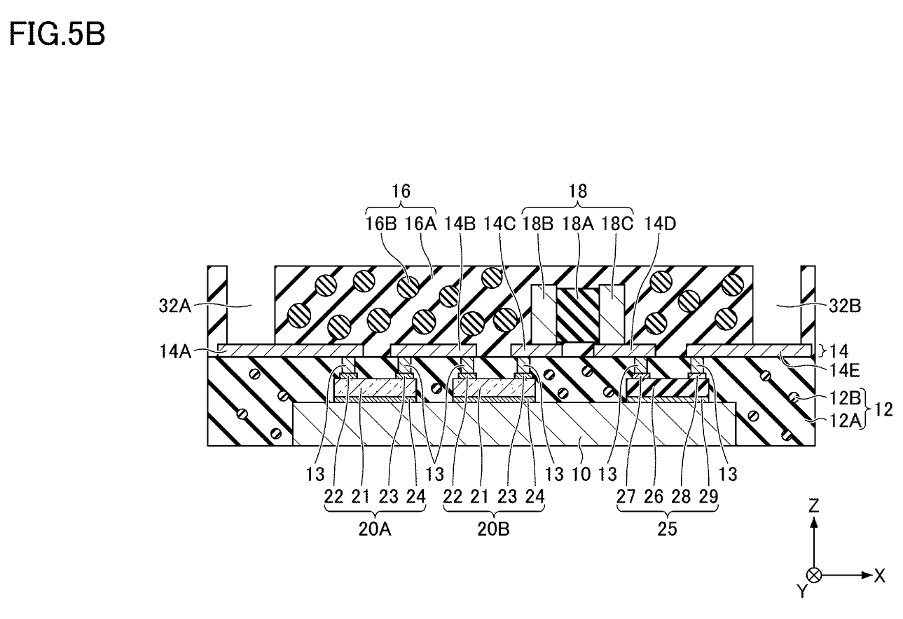

Next, as shown in FIG. 5A, through holes 32A and 32B penetrating the resin layer 16 are formed by irradiating the resin members 30A and 30B with a laser beam 35. As the laser beam 35, for example, a fundamental wave, a second harmonic wave, or a third harmonic wave of an yttrium aluminum garnet (YAG) laser beam, a carbon dioxide laser beam, an ultraviolet laser beam, or the like can be used. Since the resin members 30A and 30B have no filler, the through holes 32A and 32B can be easily formed. Resin residues 33 remain in the through holes 32A and 32B. Even when the resin members 30A and 30B have the fillers 30C, the through holes 32A and 32B can be easily formed because the particle diameter of the fillers 30C is small. In this case, the fillers may remain as the residues 33.

Next, as shown in FIG. 5B, the residues in the through holes 32A and 32B are removed (i.e., desmear treatment). The residue is removed by, for example, a chemical treatment using permanganate. Even when the resin members 30A and 30B have the fillers 30C, the remaining fillers are removed in the desmear treatment.

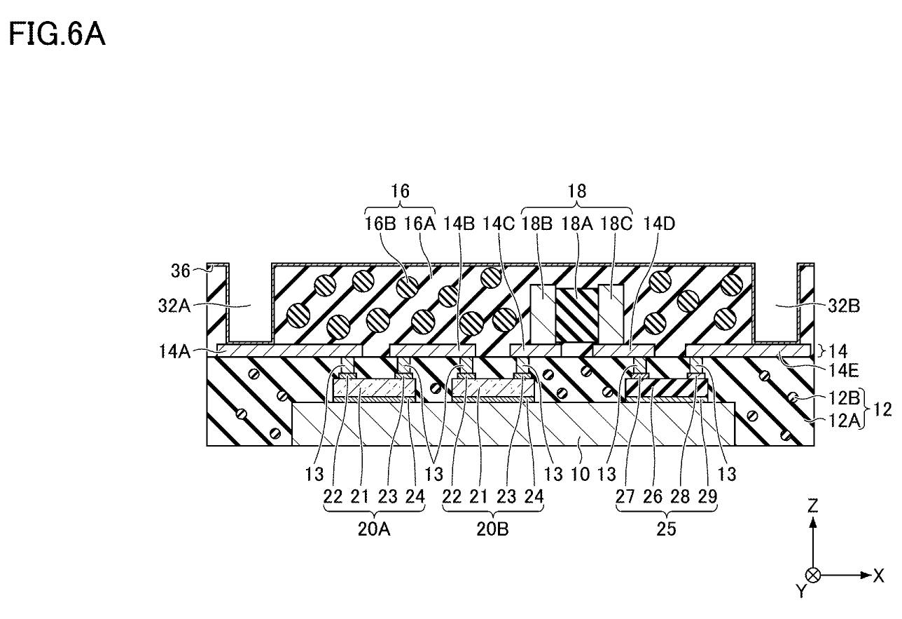

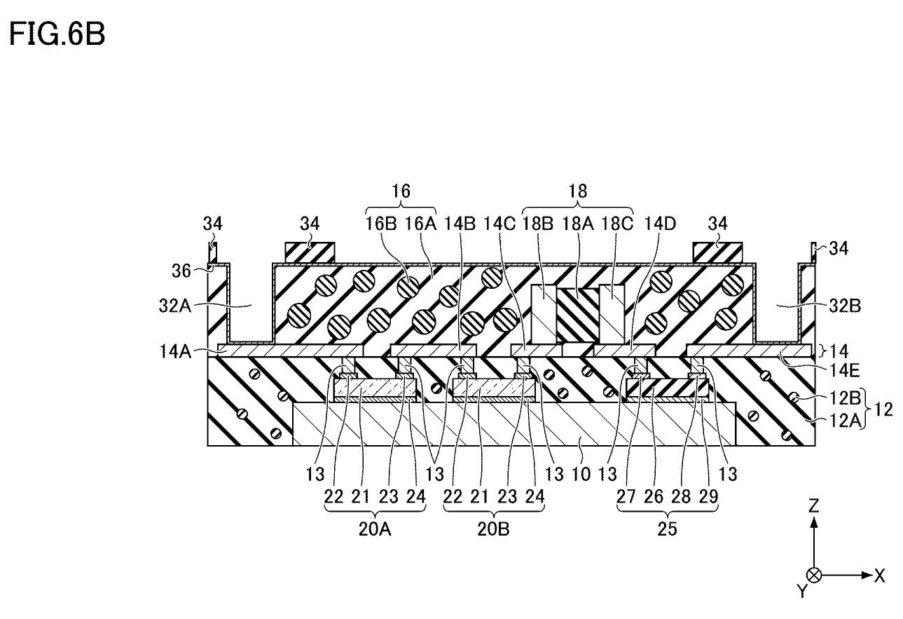

Next, as shown in FIG. 6A, a seed layer 36 is formed on inner surfaces of the through holes 32A and 32B and the upper surface of the resin layer 16. The seed layer 36 is formed using, for example, electroless plating. When an uppermost layer of the interconnect 14 is a copper layer, the seed layer 36 is, for example, a copper layer. A thickness of the seed layer 36 is, for example, 0.5 μm to 2.0 μm.

Next, as shown in FIG. 6B, a mask layer 34 is formed on the seed layer 36. The mask layer 34 is an insulating layer, and is, for example, a photoresist. The photoresist is applied on the seed layer 36, and the photoresist is exposed to light. Thereafter, the photoresist is developed, and the mask layer 34 having a desired pattern shape is formed.

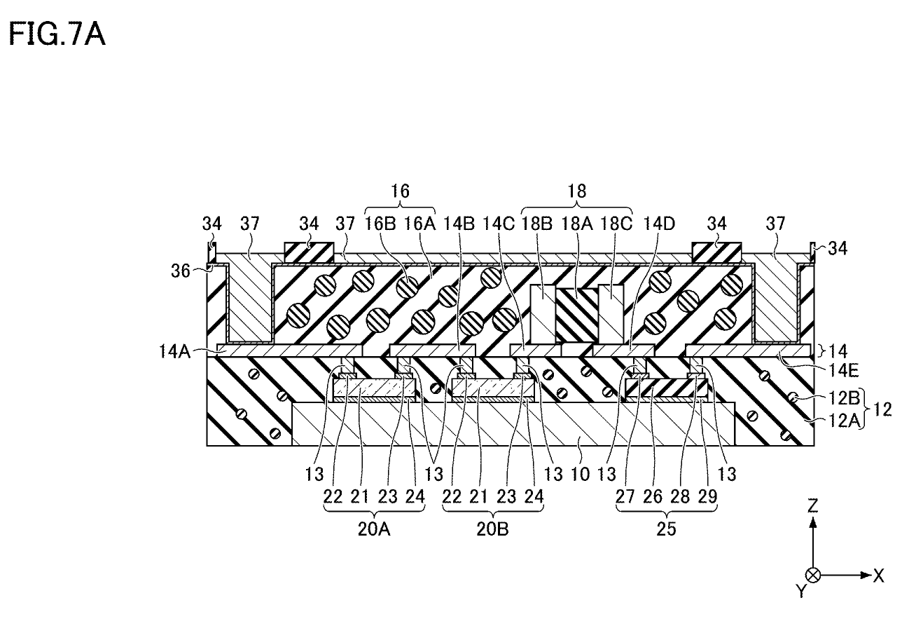

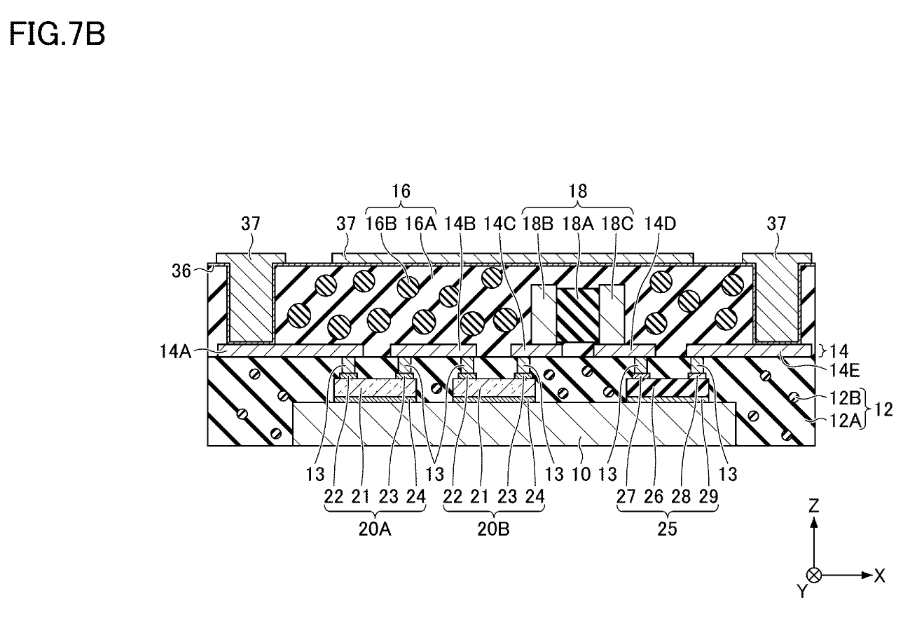

Next, as shown in FIG. 7A, a plating layer 37 is formed on the seed layer 36. The plating layer 37 is formed using, for example, electrolytic plating. The plating layer 37 is, for example, a copper layer. The plating layer 37 has a thickness of, for example, 10 μm to 50 μm. The plating layer 37 is not formed on the mask layer 34. The through holes 32A and 32B are filled with the plating layer 37.

Next, as shown in FIG. 7B, the mask layer 34 is removed. At this time, the seed layer 36 or the plating layer 37 is not removed.

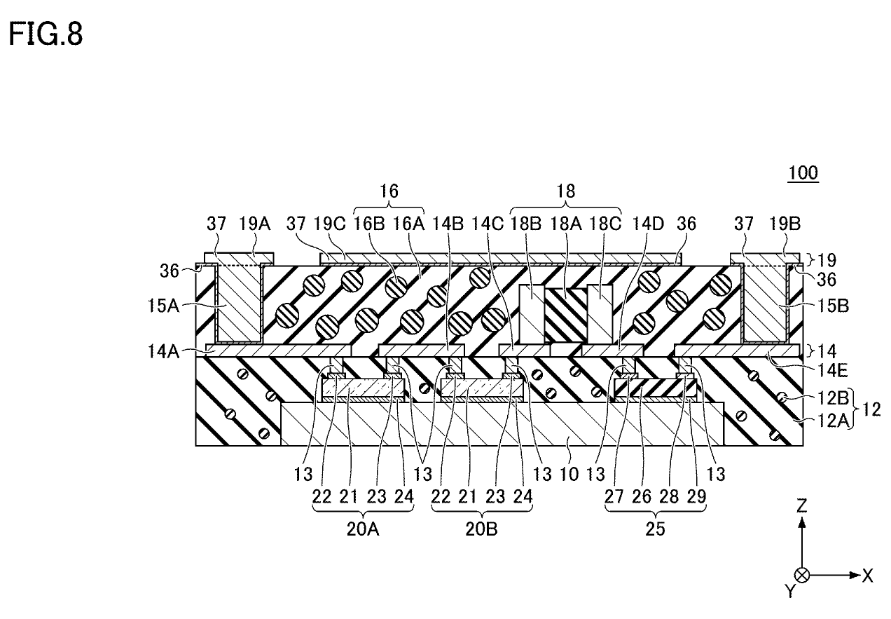

Next, as shown in FIG. 8, the seed layer 36 is removed using the plating layer 37 as a mask. The seed layer 36 is removed using, for example, dry etching. At this time, an upper portion of the plating layer 37 may be partially etched. As a result, the through electrodes 15A and 15B are formed from the seed layer 36 and the plating layer 37 in the through holes 32A and 32B. The external terminals 19A to 19C are formed from the seed layer 36 and the plating layer 37 on the resin layer 16. As described above, the semiconductor device 100 is manufactured.

### First Comparative Embodiment

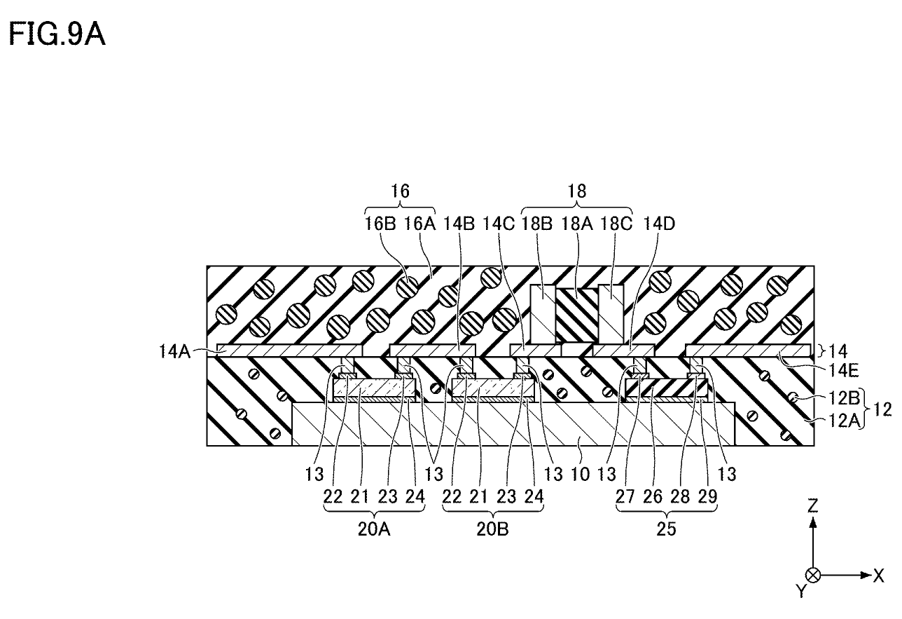

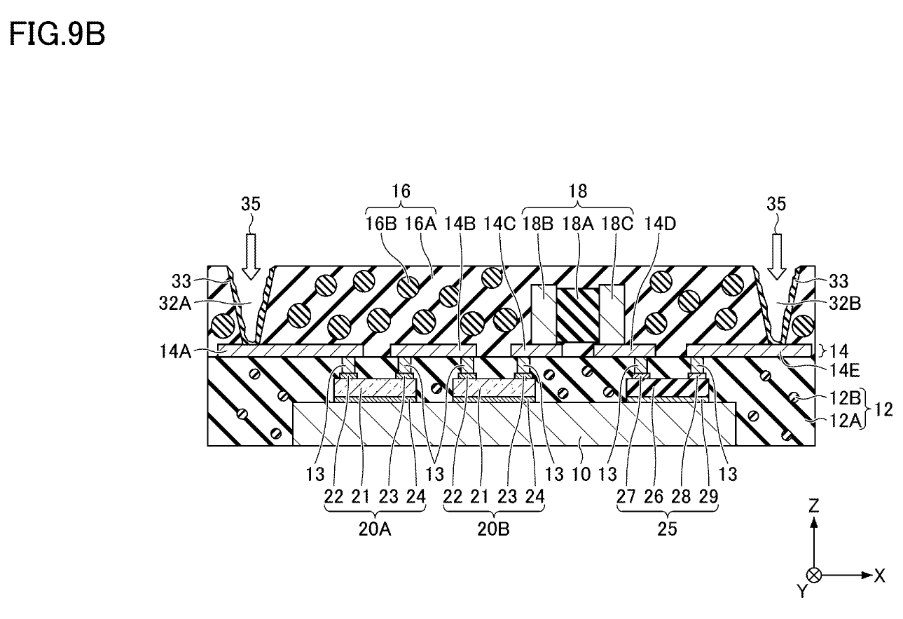

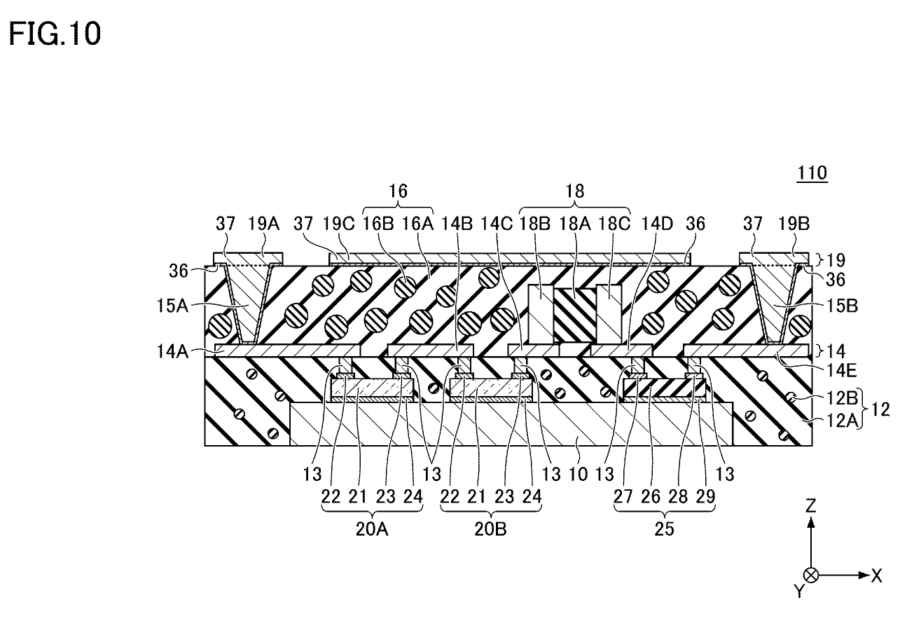

FIGS. 9A, 9B, and 10 are cross-sectional views each showing a method of manufacturing a semiconductor device according to a first comparative embodiment. As shown in FIG. 9A, after FIG. 3A, the resin layer 16 is formed on the resin layer 12 so as to cover the electronic component 18.

Next, as shown in FIG. 9B, the resin layer 16 is irradiated with the laser beam 35, and through holes 32A and 32B in the resin layer 16 are formed. At this time, the width of a lower surface of each of the through holes 32A and 32B is smaller than the width of an upper surface of each of the through holes 32A and 32B. Next, as shown in FIG. 10, the processes of FIGS. 5B-8 are performed. The width of a lower surface of each of the through electrodes 15A and 15B is smaller than the width of an upper surface of each of the through holes 15A and 15B. As described above, a semiconductor device 110 of the first comparative embodiment is manufactured.

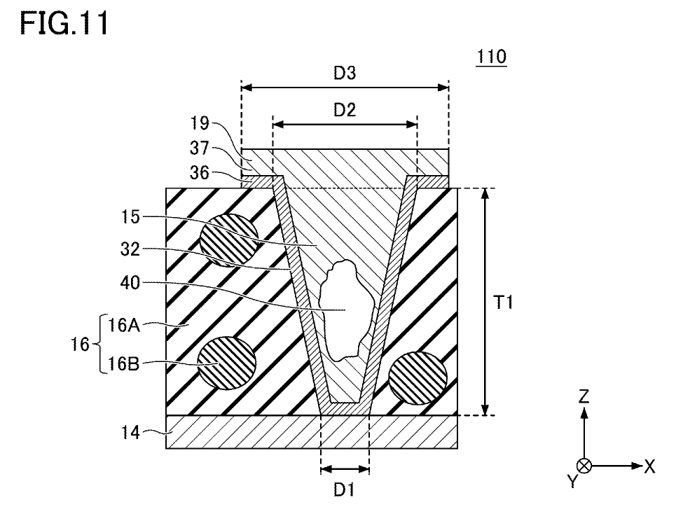

FIG. 11 is an enlarged cross-sectional view of a through electrode of a semiconductor device according to the first comparative embodiment. As shown in FIG. 11, when the resin layer 16 is formed so as to cover the electronic component 18, a thickness T1 of the resin layer 16 is, for example, 500 μm. In FIG. 9B, when the through hole 32 is formed using the laser beam 35, a width D1 of a lower surface of the through hole 32 is smaller than a width D2 of an upper surface of the through hole 32. This is because, when the resin layer 16 includes the fillers 16B having a large particle diameter, the laser beam 35 is scattered and absorbed by the fillers 16B, and the laser beam radiated deep into the resin layer 16 is weakened.

When the width D1 of the lower surface of the through electrode 15 is smaller than the width D2 of the upper surface of the through electrode 15, a contact area between the through electrode 15 and the interconnect 14 is reduced. For example, when a width D3 of the external terminal 19 is 400 μm, the width D2 is approximately 300 μm. As an example, the width D1 is 90 μm, and the width D1 is about 1/3 of the width D2.

In FIG. 7A, when the plating layer 37 is formed on the seed layer 36, when the width D1 of the lower surface of the through hole 32 is small, plating solution may not enter the through hole 32, and a cavity 40 may be formed in the plating layer 37. Due to the cavity 40, resistance of the through electrode 15 is increased.

### Second Comparative Embodiment

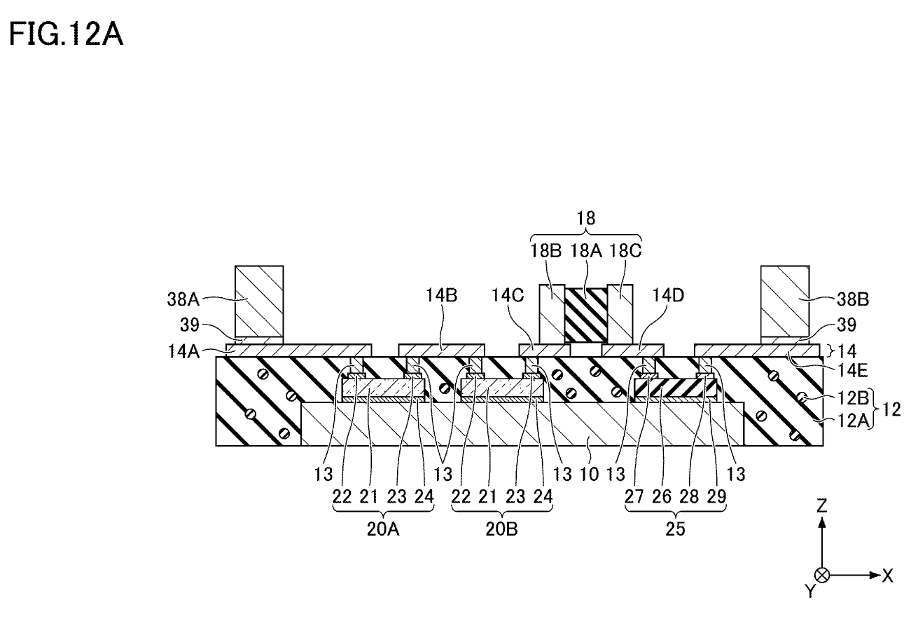

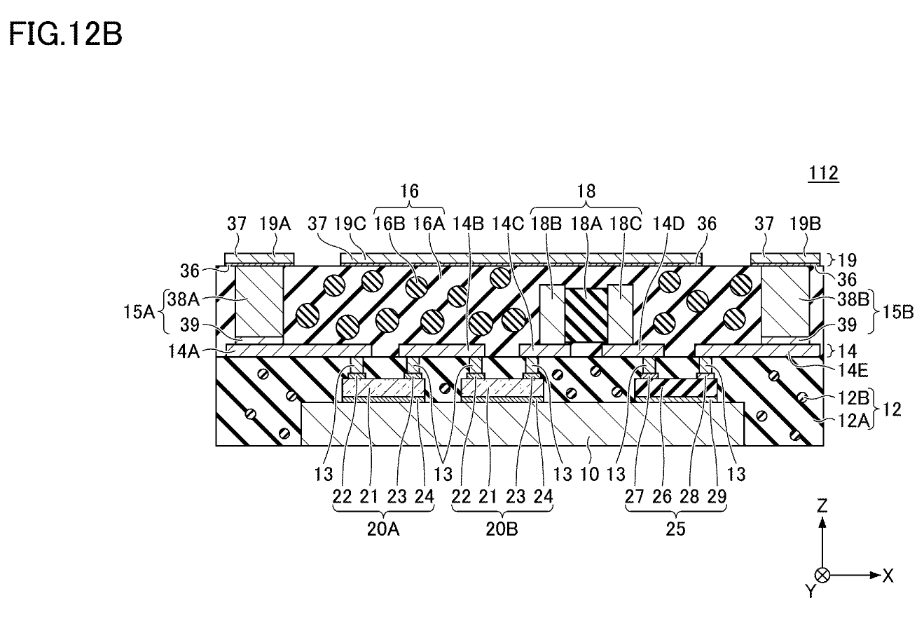

FIGS. 12A and 12B are cross-sectional views each showing a method of manufacturing a semiconductor device according to a second comparative embodiment. As shown in FIG. 12A, after the process shown in FIG. 3A, metal pillars 38A and 38B are mounted on the interconnect 14. The metal pillars 38A and 38B are bonded to the interconnect 14 using a conductive bonding material 39. The metal pillars 38A and 38B are, for example, copper pillars, and the conductive bonding material 39 is, for example, a metal obtained by sintering a silver paste.

Next, as shown in FIGS. 12B, 4A-8 are performed without performing FIGS. 5A and 5B. Thus, the through electrode 15A is formed from the metal pillar 38A and the conductive bonding material 39. The through electrode 15B is formed from the metal pillar 38B and the conductive bonding material 39. As described above, a semiconductor device 112 of the second comparative embodiment is manufactured.

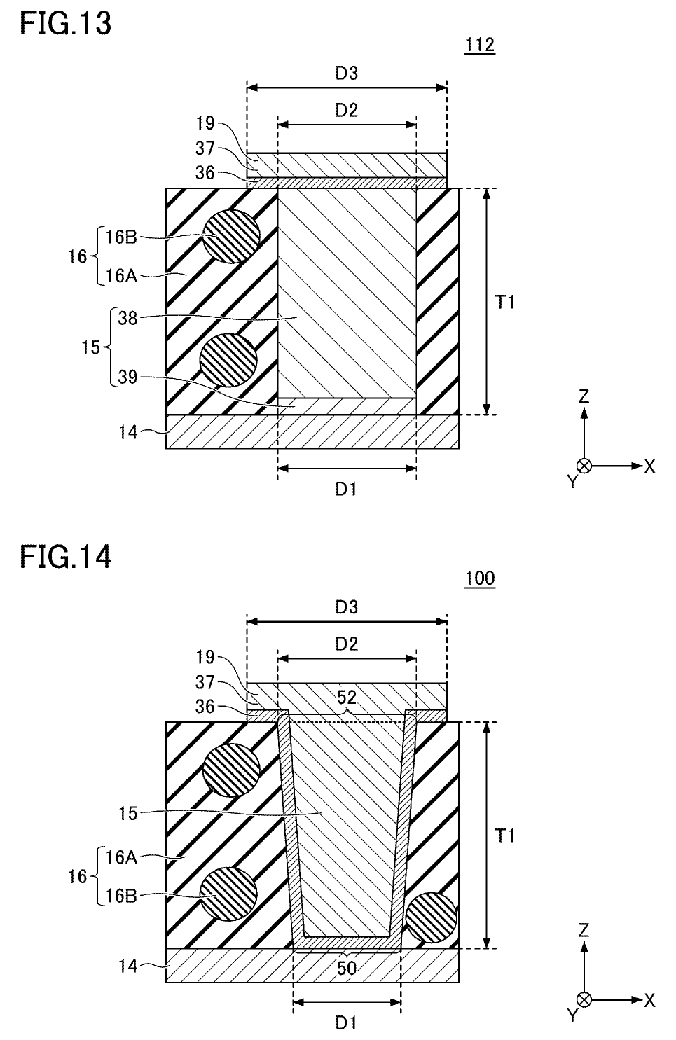

FIG. 13 is an enlarged cross-sectional view of a through electrode of a semiconductor device according to the second comparative embodiment. As shown in FIG. 13, by using a metal pillar 38 as the through electrode 15, the width D1 of the lower surface of the through electrode 15 can be made substantially the same as the width D2 of the upper surface of the through electrode 15. Thus, when the width D3 of the external terminal 19 is 400 μm and the width D2 is 300 μm, for example, the width D1 can be 300 μm. This increases the contact area between the through electrode 15 and the interconnect 14. However, since the conductive bonding material 39 has a high resistivity, contact resistance between the through electrode 15 and the interconnect 14 is high. In addition, since the conductive bonding material 39 has a weak bonding strength with the interconnect 14, the through electrode 15 may be peeled off from the interconnect 14.

As described above, in the first comparative embodiment and the second comparative embodiment, when the external terminals 19A and 19B are made small in order to miniaturize the semiconductor device, it is difficult to appropriately connect the external terminals 19A and 19B to the interconnect 14.

In the semiconductor device shown in FIG. 14 of Patent Literature 2, a width of a lower surface of a through electrode and a width of an upper surface of the through electrode are shown to be substantially equal to each other. However, Patent Literature 2 does not describe a method of forming the through electrode, and it is considered that the through electrode is formed by any one of the methods of the first comparative embodiment or the second comparative embodiment. When the through electrode is formed by using the method of the first comparative embodiment, it is considered that the width D1 is smaller than the width D2 as in the first comparative embodiment. When the through electrode is formed by using the method of the second comparative embodiment, it is considered that the through electrode and the interconnect are not directly connected.

### Description of First Embodiment

According to the first embodiment, as shown in FIGS. 2A-2C, the member 101 including the base 10, the semiconductor chips 20A and 20B, the resin layer 12 (first resin layer), and the interconnects 14A to 14E is prepared. As shown in FIG. 3A, the electronic component 18 is mounted on the interconnects 14C and 14D of the member 101. As shown in FIG. 3B, the resin members 30A and 30B are mounted on the interconnects 14A and 14E, respectively. As shown in FIGS. 4A and 4B, the resin layer 16 is formed on the resin layer 12 so as to cover the electronic component 18 and the resin members 30A and 30B and expose upper surfaces of the resin members 30A and 30B from the resin layer 16 (second resin layer). As shown in FIGS. 5A and 5B, the resin members 30A and 30B are removed to form through holes 32A and 32B respectively connected to the interconnects 14A and 14E. As shown in FIGS. 6A-8, the through electrode 15A electrically connected to the interconnect 14A is formed in the through hole 32A, and the through electrode 15B electrically connected to the interconnect 14B is formed in the through hole 32B. The external terminals 19A and 19B electrically connected to the through electrodes 15A and 15B, respectively, are formed on the resin layer 16.

FIG. 14 is an enlarged cross-sectional view of a through electrode of a semiconductor device according to the first embodiment. As shown in FIG. 14, in the semiconductor device 100, the through holes 32A and 32B are formed using the resin members 30A and 30B, respectively, instead of forming the through holes 32A and 32B using the laser beam 35 in the resin layer 16 having the fillers 16B with a large particle diameter as in FIG. 9B of the first comparative embodiment. Thus, the width D1 of the lower surface of the through electrode 15 is substantially the same as the width D2 of the upper surface of the through electrode 15. Thus, the contact resistance between the through electrode 15 and the interconnect 14 can be reduced. In addition, when the plating layer 37 is formed, the formation of the cavity 40 as shown in FIG. 11 can be reduced. This can reduce the resistance of the through electrode 15. The width D1 may be, for example, equal to or greater than 0.7 times, equal to or greater than 0.8 times, or equal to or greater than 0.9 times the width D2. The width D1 may be equal to or less than the width D2. The width D1 is a width of a first region 50 where the through electrode 15 is in contact with the interconnect 14. The width D2 is a width of a second region 52 where the through electrode 15 is in contact with the external terminal 19. When the through electrode 15 has a circular planar shape, the widths D1 and D2 are the diameters of the first region 50 and the second region 52 in the planar shape, respectively.

In the first embodiment, the seed layer 36 and the interconnect 14, each containing the same element (for example, copper) as a main component, are directly connected as shown in FIG. 14, without using the conductive bonding material 39 as shown in FIG. 13 of the second comparative embodiment. This can reduce the contact resistance between the through electrode 15 and the interconnect 14. Further, since the seed layer 36 of the through electrode 15 and the interconnect 14 are directly connected to each other, the bonding strength between the through electrode 15 and the interconnect 14 can be increased, and peeling of the through electrode 15 from the interconnect 14 can be reduced. Note that, "a certain layer contains a certain element as a main component" means that a concentration of the certain element in the certain layer is 50 atom% or more, and the concentration of the certain element in the certain layer may be, for example, 80 atom% or more, or 90 atom% or more.

As described above, in the semiconductor device 100 of the first embodiment, the contact resistance between the through electrode 15 and the interconnect 14 can be reduced, and the bonding strength between the through electrode 15 and the interconnect 14 can be increased. Thus, the external terminal 19 and the interconnect 14 can be appropriately connected.

When the thickness T1 of the resin layer 16 is larger than the width D2 of the second region 52, the width D1 is small in the first comparative embodiment as shown in FIG. 11, and the contact resistance between the through electrode 15 and the interconnect 14 is high. Thus, when the thickness T1 of the resin layer 16 is larger than the width D2 of the second region 52, the through holes 32A and 32B can be formed using the resin members 30A and 30B, respectively. Thus, the external terminal 19 and the interconnect 14 can be appropriately connected. The thickness T1 may be, for example, 1.1 or more times, or 1.2 or more times the width D2.

In the first comparative embodiment, as shown in FIG. 9B, when the resin layer 16 includes the fillers 16B (first fillers), the through holes 32A and 32B are formed by radiating the laser beam 35. This reduces the width of the lower surface of each of the through holes 32A and 32B. As shown in FIG. 11, the width D1 is approximately 1/3 of the width D2. Thus, in the first embodiment, the resin members 30A and 30B are removed as shown in FIG. 5A. As a result, the width of the lower surface of each of the through holes 32A and 32B can be made approximately the same as the width of the upper surface of each of the through holes 32A and 32B. Thus, the external terminal 19 and the interconnect 14 can be appropriately connected.

In addition, in the first embodiment, as shown in FIG. 5A, even when the through holes 32A and 32B are formed using the laser beam 35, the resin members 30A and 30B include no filler or include the fillers 30C (second fillers) having an average particle diameter smaller than the average particle diameter of the fillers 16B. With this configuration, the width of the lower surfaces of the through holes 32A and 32B are less likely to be reduced as shown in FIG. 5A. Thus, as shown in FIG. 14, the width D1 can be 0.7 or more times the width D2.

An average particle diameter of the fillers 30C is, for example, 1/2 or less times, or 1/10 or less times an average particle diameter of the fillers 16B. The average particle diameter of the fillers 16B is, for example, 2 μm to 10 μm. The average particle diameter of the fillers 30Cs is, for example, 0.5 μm to 3 μm. When the volume ratio of the fillers 16B to the resin layer 16 is large, the width D2 tends to be small. From this viewpoint, the resin members 30A and 30B can be used when the volume ratio of the fillers 16B to the resin layer 16 is 0.5 or more. The volume ratio of the fillers 30C to the resin members 30A and 30B may be 0.3 or less.

The semiconductor chips 20A and 20B are easily affected by stress or the like, and the electronic component 18 is hardly affected by stress or the like. Thus, the average particle diameter of the fillers 16B of the resin layer 12 may be smaller than the average particle diameter of the fillers 16B of the resin layer 16. The resin layer 16 having the fillers 16B with a large average particle diameter can be formed at low cost. By using the resin members 30A and 30B, the average particle diameter of the fillers 16B can be increased. Thus, the cost of the semiconductor device 100 can be reduced.

As in FIGS. 6A-8, the through electrodes 15A and 15B are formed using plating. This allows the seed layer 36 containing the same main component as the main component of the interconnect 14 to be directly connected to the interconnect 14.

### Second Embodiment

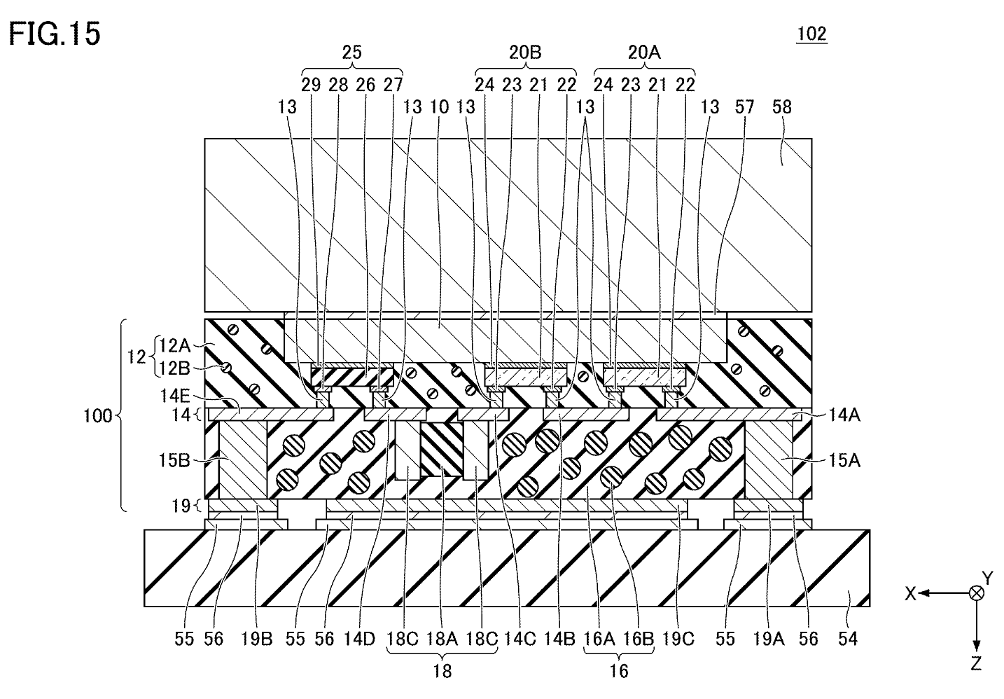

FIG. 15 is a cross-sectional view showing a module according to the second embodiment. FIG. 15 is shown upside down compared to FIG. 1. That is, the top and bottom of FIG. 1 correspond to the bottom and top of FIG. 15, respectively. As shown in FIG. 15, a module 102 includes the semiconductor device 100, a mounting substrate 54, and a heat dissipation member 58. An upper surface of the mounting substrate 54 and a lower surface of the heat dissipation member 58 are, for example, flat surfaces. An electrode 55 is provided on the mounting substrate 54. The external terminals 19A to 19C are bonded to the electrode 55 by using a bonding member 56. A surface of the base 10 opposite to a surface on which the semiconductor chips 20A and 20B are mounted is bonded to the heat dissipation member 58 using a bonding member 57.

The mounting substrate 54 is, for example, a resin substrate such as a glass epoxy resin substrate or an insulating substrate such as a ceramic substrate. The electrode 55 is a metal layer such as a gold layer or a copper layer. The bonding member 56 is conductive and is, for example, solder. The heat dissipation member 58 is a heat sink, and is a metal member such as copper or aluminum. The bonding member 57 is a bonding member having a high thermal conductivity, and is a metal or an insulator.

In the module 102 of the second embodiment, the heat dissipation member 58 is bonded to the surface of the base 10 opposite to the surface on which the semiconductor chips 20A and 20B are mounted. The mounting substrate 54 is electrically connected to the external terminals 19A to 19C. That is, in the semiconductor device 100, the base 10 is connectable to the heat dissipation member 58, and the external terminals 19A to 19C are electrically connectable to the mounting substrate 54. Thus, heat generated in the semiconductor chips 20A and 20B is conducted to the heat dissipation member 58 via the base 10 and the bonding member 57. The electrical connection from the mounting substrate 54 to the semiconductor chips 20A and 20B is performed from the electrode 55 of the mounting substrate 54 via the external terminals 19A to 19C. In this manner, in the module 102, heat dissipation and electrical connection are performed from opposite sides. In this structure, the mounting substrate 54 and the interconnect 14 are electrically connected to each other using through electrodes 15A and 15B penetrating the resin layer 16. Thus, the external terminal 19 and the interconnect 14 can be appropriately connected by forming the through electrodes 15A and 15B using the resin members 30A and 30B, respectively.

### Third Embodiment

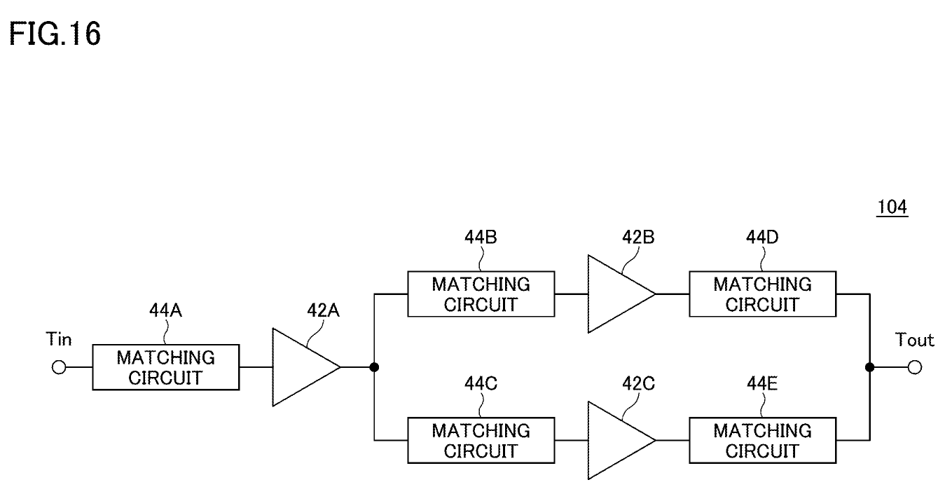

A third embodiment is an example in which the semiconductor device of the first embodiment is used in an amplification circuit. FIG. 16 is a block diagram of an amplification circuit according to the third embodiment. As shown in FIG. 16, an amplification circuit 104 includes amplifiers 42A to 42C and matching circuits 44A to 44E. The amplification circuit 104 is a two-stage amplification circuit, the amplifier 42A is a driver amplifier, and the amplifiers 42B and 42C are power amplifiers of a Doherty amplifier. A high frequency signal input from an input terminal Tin is amplified by the amplifier 42A, further amplified by the amplifiers 42B and 42C, and output from an output terminal Tout. A frequency of the high frequency signal input to the input terminal Tin and output from the output terminal Tout is, for example, 0.5 GHz to 100 GHz. When the amplification circuit 104 is used as a transmission amplification circuit of a base station for mobile communications, the frequency of the high frequency signal is, for example, 0.5 GHz to 20 GHz. The amplifiers 42A to 42C are, for example, transistors, such as FETs, and are mounted on each of the semiconductor chips 20A and 20B.

The input terminal Tin is connected to the amplifier 42A via the matching circuit 44A. The matching circuit 44A matches impedance seen from the input terminal Tin toward the matching circuit 44A with impedance seen from the matching circuit 44A toward the amplifier 42A. The output of the amplifier 42A is branched and input to the amplifier 42B and 42C via the matching circuits 44B and 44C, respectively. The matching circuit 44B matches impedance seen from the amplifier 42A toward the matching circuit 44B with impedance seen from the matching circuit 44B toward the amplifier 42B. The matching circuit 44C matches impedance seen from the amplifier 42A toward the matching circuit 44C with impedance seen from the matching circuit 44C toward the amplifier 42C. The outputs of the amplifiers 42B and 42C are combined via matching circuits 44D and 44E, respectively, and input to the output terminal Tout. The matching circuit 44D matches impedance seen from the amplifier 42B toward the matching circuit 44D with impedance seen from the matching circuit 44D toward the output terminal Tout. The matching circuit 44E matches impedance seen from the amplifier 42C toward the matching circuit 44E with impedance seen from the matching circuit 44E toward the output terminal Tout. The matching circuits 44A to 44E are formed by the passive chip 25, the electronic component 18, and the interconnect 14 of the semiconductor device 100.

In the semiconductor device 100 of the first embodiment used in the amplification circuit 104, as shown in FIG. 1, the high frequency signal input to the semiconductor chip 20A is transmitted through the interconnect 14A (first interconnect). The high frequency signal output from the semiconductor chip 20B is transmitted through the interconnect 14E (second interconnect). The through electrode 15A (first through electrode) is electrically connected to the interconnect 14A. The through electrode 15B (second through electrode) is electrically connected to the interconnect 14E. The external terminal 19A (first external terminal) is electrically connected to the through electrode 15A. The external terminal 19B (second external terminal) is electrically connected to the through electrode 15B. As described above, the high frequency signal is transmitted through the through electrodes 15A and 15B and the interconnects 14A and 14E, and when the contact resistance between the through electrode 15A and the interconnect 14A and between the through electrode 15B and the interconnect 14E is increased, the high-frequency characteristics are deteriorated. Thus, the resin members 30A and 30B can be used.

The semiconductor chips 20A and 20B include amplifiers 42A to 42C that amplify the high frequency signal. This enables the external terminals 19A to 19C and the interconnect 14 to be appropriately connected in the amplification circuit.

The embodiments disclosed herein are to be considered in all respects as illustrative and not restrictive. The scope of the present disclosure is defined by the appended claims rather than by the foregoing description, and all changes that come within the meaning and range of equivalency of the claims are intended to be embraced therein.

What is claimed is:

1. A semiconductor device comprising:
a base;
a semiconductor chip mounted on the base;
a first resin layer covering the semiconductor chip and provided on the base;
an interconnect provided on the first resin layer and electrically connected to the semiconductor chip;
an electronic component mounted on the interconnect and electrically connected to the interconnect;
a second resin layer covering the electronic component and provided on the first resin layer;
a through electrode penetrating the second resin layer and electrically connected to the interconnect; and
an external terminal provided on the second resin layer and electrically connected to the through electrode,
wherein the through electrode includes a layer whose main component is a same element as a main component of the interconnect, the layer of the through electrode and the interconnect being directly connected to each other, and
wherein the through electrode includes a first region in contact with the interconnect and a second region in contact with the external terminal, and a width of the first region is equal to or greater than 0.7 times a width of the second region.

2. The semiconductor device according to claim 1, wherein the second resin layer includes fillers.

3. The semiconductor device according to claim 1, wherein the second resin layer has a thickness larger than the width of the second region.

4. The semiconductor device according to claim 1, wherein the base has a surface to which a heat dissipation member is connectable, the surface being opposite to a surface on which the semiconductor chip is mounted, and
wherein the external terminal is electrically connectable to a mounting substrate.

5. The semiconductor device according to claim 1,
wherein the interconnect includes a first interconnect through which a frequency signal input to the semiconductor chip is to be transmitted, and a second interconnect through which the frequency signal output from the semiconductor chip is to be transmitted,
wherein the through electrode includes a first through electrode electrically connected to the first interconnect, and a second through electrode electrically connected to the second interconnect, and
wherein the external terminal includes a first external terminal electrically connected to the first through electrode, and a second external terminal electrically connected to the second through electrode.

6. The semiconductor device according to claim 5, wherein the semiconductor chip includes an amplifier configured to amplify the frequency signal.

7. A module comprising:
the semiconductor device according to claim 1;
a heat dissipation member bonded to a surface of the base opposite to a surface on which the semiconductor chip is mounted; and
a mounting substrate electrically connected to the external terminal.

8. A method of manufacturing a semiconductor device, the method comprising: preparing a member including a base, a semiconductor chip mounted on the base, a first resin layer covering the semiconductor chip and provided on the base, and an interconnect provided on the first resin layer and electrically connected to the semiconductor chip;
mounting an electronic component on the interconnect of the member;
mounting a resin member on the interconnect;
forming a second resin layer on the first resin layer so as to cover the electronic component and the resin member and expose an upper surface of the resin member from the second resin layer;
forming a through hole connected to the interconnect by removing the resin member; and
forming a through electrode electrically connected to the interconnect in the through hole, and an external terminal electrically connected to the through electrode on the second resin layer.

9. The method of manufacturing a semiconductor device according to claim 8,
wherein the second resin layer includes first fillers,
wherein the resin member includes second fillers having an average particle diameter smaller than an average particle diameter of the first fillers, or includes no filler, and
wherein the forming the through hole includes forming the through hole by irradiating the resin member with a laser beam.

10. The method of manufacturing a semiconductor device according to claim 8,
wherein the forming the through electrode includes forming the through electrode by plating.
